(19) United States
(12) Patent Application Publication
(10) Pub. No.: US 2013/0049798 A1
(43) Pub. Date: Feb. 28, 2013

(54) MOTHERBOARD WITH DUAL NETWORK CARD CONNECTORS AND LOW SIGNAL REFLECTIVITY

(71) Applicants: PEI-YI CHANG, Tu-Cheng (TW); CHENG-CHUAH LIN, Tu-Cheng (TW)

(72) Inventors: PEI-YI CHANG, Tu-Cheng (TW); CHENG-CHUAH LIN, Tu-Cheng (TW)

(73) Assignee: HON HAI PRECISION INDUSTRY CO., LTD., Tu-Cheng (TW)

(21) Appl. No.: 13/300,620

(22) Filed: Nov. 20, 2011

(30) Foreign Application Priority Data
Aug. 24, 2011 (TW) 100215832

(51) Int. Cl. H03K 17/16

(52) U.S. Cl. 326/30

(57) ABSTRACT

An exemplary motherboard includes a controller, and two different network card connectors. At least one of the two network card connectors is electronically connected to the controller via a resistor. A user of the motherboard may choose to use either the first network card connector, or the second network card connector, or the first network card connector and the second network card connector simultaneously.

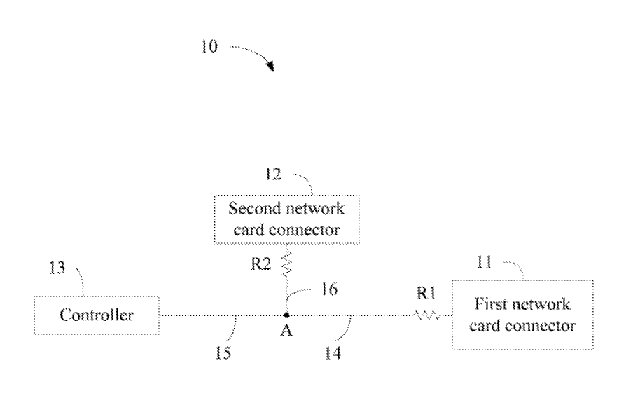

### BACKGROUND

1. Technical Field

The exemplary disclosure generally relates to motherboards, and particularly to a motherboard with dual network card connectors and low signal reflectivity.

2. Description of Related Art

A motherboard may have a network card connector positioned thereon. The network card connector is used to hold a network card and enable the motherboard to connect to an external network. Network cards may be different for different kinds of networks. For example, there is the 10M/100M network card and the 1000M network card, which are used for different kinds of networks. Many motherboards have only one type of network card connector. In use of such a motherboard, only one type of network is available to the user via the network card connector, which may be inconvenient.

Therefore, there is room for improvement within the art.

### BRIEF DESCRIPTION OF THE DRAWING

Many aspects of the embodiments can be better understood with reference to the drawing. In the drawing, the emphasis is placed upon clearly illustrating the principles of the disclosure.

The drawing is a circuit diagram of an exemplary motherboard having a first network card connector, a second network card connector and a controller.

### DETAILED DESCRIPTION

The FIGURE shows an exemplary embodiment of a motherboard with dual network card connectors and low signal reflectivity. The motherboard 10 includes a first network card connector 11, a second network card connector 12, a controller 13, a first signal cable 14, a second signal cable 15, a third signal cable 16, at least one first resistor R1, and at least one second resistor R2. The first signal cable 14, the second signal cable 15 and the third signal cable 16 are electronically connected to a node labeled “A”. In the illustrated embodiment, there is a single first resistor R1 and a single second resistor R2. The node A is electronically connected to the first network card connector 11 via the first signal cable 14 and the first resistor R1, is electronically connected to the controller 13 via the second signal cable 15, and is electronically connected to the second network card connector 12 via the third signal cable 16 and the second resistor R2. The controller 13 may selectively communicate either with the first network card connector 11 only, or with the second network card connector 12 only, or simultaneously with both network card connectors 11, 12.

The first network card connector 11 provides a temporary or permanent mounting for a first network card (not shown), and the second network card connector 12 provides a temporary or permanent mounting for a second network card (not shown), wherein the two network cards are different. Therefore, in use of the motherboard 10, users can choose to use either the first network card or the second network card, or use the first network card and the second network card simultaneously.

The first resistor R1 is positioned adjacent to the first network card connector 11. When a network card is not installed in the first network card connector 11 and the second network card connector 12 is connected to a second network card, the first resistor R1 is used to prevent the first signal cable 14 from inducing reflection signals which causes communication distortion, errors and so forth. The resistance of the first resistor R1 is equal to a characteristic impedance of the first signal cable 14.

The second resistor R2 is positioned adjacent to the second network card connector 12. When a network card is not installed in the second network card connector 12 and the first network card connector 11 is connected to a first network card, the second resistor R2 is used to prevent the third signal cable 16 from inducing reflection signals which causes communication distortion, errors and so forth. The resistance of the second resistor R2 is equal to a characteristic impedance of the third signal cable 16.

In an alternative embodiment, provided that a very short signal path exists between the first network card connector 11 and the node A, the first resistor R1 may be omitted. In such case, the second resistor R2 is still retained. In another alternative embodiment, provided that a very short signal path exists between the second network card connector 12 and the node A, the second resistor R2 may be omitted. In such case, the first resistor R1 is still retained.

The first signal cable 14 can be one signal line or a group of signal lines, and each of the second signal cable 15 and the third signal cable 16 can be one signal line or a group of signal lines accordingly. When the first signal cable 14 is a group of signal lines, each of the signal lines of the first signal cable 14 is connected via a respective first resistor R1 to the first network card connector 11. When the third signal cable 16 is a group of signal lines, each of the signal lines of the third signal cable 16 is connected via a respective second resistor R2 to the second network card connector 12.

Since the first network card connector 11 and the second network card connector 12 are both electronically connected to the controller 13, users can select to use either the first network card or the second network card, or use the two network cards simultaneously.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments.

What is claimed is:

1. A motherboard comprising:
a controller;
a first signal cable;
a second signal cable electronically connected to the first signal cable via a node;
a third signal cable electronically connected to the node between the first signal cable and the second signal cable;
a first network card connector electronically connected to the controller via the first signal cable and the second signal cable;
a second network card connector electronically connected to the controller via the third signal cable and the second signal cable; and
at least one resistor selected from the group consisting of a first resistor electronically connected between the first network card connector and the first signal cable and a second resistor electronically connected between the second network card connector and the third signal cable, wherein the controller is selectively able to communicate either with the first network card connector only or with the second network card connector only or simultaneously with both the first network card connector and the second network card connector.

2. The motherboard in claim 1, wherein the first resistor is positioned adjacent to the first network card connector.

3. The motherboard in claim 1, wherein the second resistor is positioned adjacent to the second network card connector.

4. The motherboard in claim 1, wherein the resistance of the first resistor is equal to a characteristic impedance of the first signal cable.

5. The motherboard in claim 1, wherein the resistance of the second resistor is equal to a characteristic impedance of the third signal cable.

6. The motherboard in claim 1, wherein the first signal cable comprises one signal line or a group of signal lines, and each of the second signal cable and the third signal cable comprises one signal line or a group of signal lines accordingly.

7. A motherboard comprising:
a controller;
a first signal cable;
a second signal cable electronically connected to the first signal cable via a node;
a third signal cable, the second signal cable electronically connected to the third signal cable via the node;
a first network card connector electronically connected to the controller via a first resistor, the first signal cable and the second signal cable; and
a second network card connector electronically connected to the controller via a second resistor, the third signal cable and the second signal cable;
wherein the controller is selectively able to communicate either with the first network card connector only or with the second network card connector only or simultaneously with both the first network card connector and the second network card connector.

8. The motherboard in claim 7, wherein a resistance of the first resistor is equal to a characteristic impedance of the first signal cable, and a resistance of the second resistor is equal to a characteristic impedance of the third signal cable.

9. The motherboard in claim 7, wherein the first resistor is positioned adjacent to the first network card connector.

10. The motherboard in claim 7, wherein the second resistor is positioned adjacent to the second network card connector.
